(19) United States
(12) Patent Application Publication
(10) Pub. No.: US 2026/0028748 A1
(43) Pub. Date: Jan. 29, 2026

(54) Czochralski Monocrystalline Forming Process and Application Thereof

(71) Applicants: QINGHAI GOKIN SOLAR TECHNOLOGY CO., LTD., Qinghai (CN); GOKIN SOLAR CO., LTD., Guangdong (CN)

(72) Inventors: Le QIAO, Guangdong (CN); Zhiqun XU, Guangdong (CN); Qi WANG, Guangdong (CN); Bin SUN, Guangdong (CN); Mingquan FU, Guangdong (CN)

(73) Assignees: QINGHAI GOKIN SOLAR TECHNOLOGY CO., LTD., Qinghai (CN); GOKIN SOLAR CO., LTD, Guangdong (CN)

(21) Appl. No.: 18/996,771

(22) PCT Filed: Dec. 1, 2023
(86) PCT No.: PCT/CN2023/135745

§ 371 Date: Jan. 17, 2025

(30) Foreign Application Priority Data
Dec. 30, 2022 (CN) 202211731920.1

(51) Int. Cl. C30B 15/22; C30B 15/04; C30B 15/10; C30B 15/14; C30B 29/06

(52) U.S. Cl. CPC C30B 15/22; C30B 15/04; C30B 15/10; C30B 15/14; C30B 29/06

(57) ABSTRACT

Disclosed is czochralski monocrystalline forming process and application thereof. A barium powder scattering position, a position of a crucible for melting, and a melting power in material preparing and melting procedures are changed and optimized: when the barium powder scattering position is at ⅔ of a position above a lower part of a straight arm of the crucible in the vertical direction: the crucible for melting is at a position of −50 mm at the beginning of melting, and at a position of 30 mm when the linear size of a non-melted block at the later stage of melting is 200 mm-300 mm; a main heater power of the melting power is 85 KW, and a bottom heater power is 70 KW.

### CROSS-REFERENCE TO RELATED APPLICATIONS

The present application is a National Stage of International Patent Application No: PCT/CN2023/135745 filed on Dec. 1, 2023, which application claims priority to Chinese Application No. 202211731920.1, filed on Dec. 30, 2022, the disclosure of which is hereby incorporated again by reference in its entirety.

### TECHNICAL FIELD

The present disclosure belongs to the field of monocrystalline technologies, and specifically relates to czochralski monocrystalline forming process and application thereof.

### BACKGROUND

In a czochralski monocrystalline process, a crystal pulling process needs to undergo the following steps: material preparation→material melting (re-feeding)→crystal seeding→shoulder placement→shoulder rotation→equal diameter→finishing. At present, the performance of first seeding and shouldering is not ideal due to the material preparing and melting stages of the crystal pulling process. Existing technologies have disadvantages in a barium carbonate powder scattering position, a position of a crucible for melting, and a melting power, herein in a material preparing and crucible loading procedure, barium carbonate powder needs to be scattered on an inner wall of the crucible. Since the periphery of the crucible is the closest to a main heater during the material melting process, a silicon material block closest to the crucible wall is melted firstly, and the material block near the inner wall of the crucible firstly becomes silicon liquid and flows to the bottom of the crucible under the high-temperature melting of the heater. However, the position of barium carbonate powder scattering in the existing technologies is not thoroughly researched, or as disclosed in CN107460538A, uniformly attaching the barium carbonate powder to the inner wall of the crucible bottom corner is not beneficial to quick dissolution of the barium carbonate powder into the silicon liquid, this directly delays the process of decomposing the barium carbonate powder into barium oxide, and ultimately reacting barium oxide and silicon dioxide to form barium silicate, and the presence of barium silicate also promotes formation of a dense crystalline quartz layer at a relatively low temperature in glassy quartz; and in a material melting procedure, the position of the crucible is usually placed at a lower limit position of the crucible (usually a position of about −110 mm), during the material melting, the crucible position is kept unchanged, and after all the silicon material blocks are melted into solution, operations such as crystal seeding and shoulder placement may be performed. The disadvantages of this material melting procedure are as follows: firstly, the uppermost material block of the crucible is far away from a high-temperature area of a heater after material collapse, which affects the efficiency of the material melting; secondly, the upper part of the crucible is gradually exposed in the later stage of melting, which may easily cause abnormity such as edge collapse and deformation of the crucible; and thirdly, the crucible position is always at the lower limit, which may cause the barium powder to withstand high-temperature baking during the material melting, which is not beneficial to the formation of dense quartz on the inner wall of the crucible, and thus it has a negative impact on crucible seeding and shouldering. In addition, the power of the material melting is usually given based on unit configuration and thermal field configuration of a power cabinet. For thermal fields with a size of 36 inches or more, the main heater power is mostly 100 KW-110 KW, and the bottom heater power is 80 KW-90 KW. The excessive material melting power may cause an excessive high temperature inside a furnace during melting, and the excessive high temperature may accelerate transformation of glassy quartz to crystalline quartz. The square quartz here is not a dense protective layer, which leads to release of quartz microparticles and microbubbles in a transparent layer of the crucible quartz, interfering with an interface of crystal growth and causing a phenomenon of difficult crystallization. Chinese patent CN106319620A discloses a crystal pulling method for czochralski monocrystalline, it includes seven steps: material loading, material melting, impurity extraction, stabilization treatment, crystal seeding, shoulder placement, and finishing. In the material loading step, a re-pulling material is placed at the edge of the quartz crucible, and a polycrystalline silicon raw material is placed in the middle of the quartz crucible. In the material melting step, the heater power is increased by 10 KW-15 kW at the 2nd hour compared to the conventional power. In the impurity extraction step, the quartz crucible is rotated and the main heater power is reduced to the crystal seeding power, which solves the problem of high cost and low quality of poor-quality polycrystalline silicon in the czochralski monocrystalline. However, this process is cumbersome and mainly aimed at solving the problem of crystal impurities, without considering the problem of survival rate.

The above process is prone to causing difficulty in crystal formation during the first seeding and shouldering. Therefore, acquiring a czochralski monocrystalline forming process with a higher first seeding and shouldering survival rate is of great significance for the quality and production efficiency of monocrystalline forming.

### SUMMARY

In view of problems existing in existing technologies, the present disclosure provides czochralski monocrystalline forming process and application thereof, which aims to reduce the number of times of first seeding and shouldering and improve the survival rate of the first seeding and shouldering by a set of the innovative optimization processes of changing and optimizing a barium powder scattering position, a position of a crucible for melting, and a melting power in material preparing and melting procedures.

In a first aspect, the present disclosure provides a czochralski monocrystalline forming process, including the following steps.
S1, material preparation

A raw material for crystal pulling is put into a quartz crucible container, and the raw material includes a solid silicon material, a dopant, and barium carbonate powder.
S2, material melting

A heater is started, and the solid silicon material in the crucible is melted into liquid silicon at a high temperature.
S3, crystal seeding

After a seed crystal is inserted for high-temperature melting, fine crystal seeding is performed, the crystal seeding power is 60 KW-80 KW, and dislocation caused by thermal shock during the insertion of the seed crystal into the liquid surface is eliminated.
S4, shoulder placement

By reducing the pulling speed to 30 mm/h-100 mm/h, the power is gradually decreased by 8 KW-15 KW compared to the crystal seeding power, and the crystal diameter is rapidly increased to a required diameter of a crystal rod.
S5, shoulder rotation

In the later stage of shoulder rotation, by increasing the pulling speed, the transition process of the crystal that mainly shows a flat growth trend to a relatively stable equal diameter state is changed.
S6, equal diameter

After the shoulder placement is completed, the pulling speed is adjusted, so that the diameter of the crystal rod basically remains unchanged, and the diameter of the crystal rod is kept between ±2 mm.
S7, finishing

After the equal diameter growth, the pulling speed and power are adjusted, so that the diameter of the crystal rod is reduced until the crystal rod is separated from the silicon liquid.

Further, calculated by mass percentage, the addition amount of the solid silicon material in Step S1 is 50%-60% of the full crucible feeding amount; the addition amount of the barium carbonate powder is 2 g-5 g; and the addition amount of the dopant may refer to GB/T13389-2014 and be calculated according to the resistivity requirements before being added.

Further, the crucible in Step S1 is 32-inch, 36-inch, and 40-inch quartz crucibles.

Further, the dopant in Step S1 includes but not limited to a boron mother alloy, a gallium mother alloy, and a phosphorus mother alloy and the like.

Further, the position of scattering the barium carbonate powder in Step S1 is located in the vertical direction at ½-⅔ above a lower part of a straight arm of the crucible, and located in the horizontal direction at a distance of 10 mm-40 mm from the edge of the crucible.

Further, during the material melting process in Step S2, the position of the crucible is changed: a position in which the upper edge of the crucible and the upper edge of the heater are flush is marked as 0 mm, it is positive above 0 mm and negative below 0 mm, at the beginning of melting, the crucible position is located at −70 mm to −50 mm, the crucible position is located at −50 mm-0 mm when the melting is performed for 4 h, and the crucible position is located at 0 mm-30 mm when the melting is performed for 6 h.

Further, during the material melting process in Step S2, when the linear size of a non-melted block in the later stage of the melting is 200-300 mm, the crucible position should be at −30 mm-30 mm.

Further, during the material melting process in Step S2, the main heater power range of the melting power is 80 KW-90 KW, and the bottom heater power range is 60 KW-80 KW.

Further, the number of times of first seeding and shouldering (the number of times of seeding and shouldering is defined as the successful crystal seeding and entering the shoulder placement procedure) during the crystal seeding process in Step S3 is 1.5 times-2.5 times.

Further, the adjustment of the pulling speed in Step S6 is achieved by using proportion integration differentiation (PID) to adjust the pulling speed, it is 50 mm/h-140 mm/h.

Further, the adjustment of the pulling speed in Step S7 is 1 times-1.5 times of the pulling speed before the finishing, it is approximately 90 mm/h-150 mm/h.

Further, the power in Step S7 is an equal diameter power plus 10 KW-20 KW, it is approximately 70 KW-90 KW.

In a second aspect, the present disclosure further provides monocrystalline silicon prepared by the czochralski monocrystalline forming process.

In a third aspect, the present disclosure further provides application of monocrystalline silicon in a semiconductor, but not limited to the semiconductor.

Compared with the existing technologies, the beneficial effects of the technical scheme of the present disclosure are as follows.

(1) According to the czochralski monocrystalline forming process and the application thereof in the present disclosure, the position of the barium carbonate powder during the material preparing process is adjusted, the position of scattering the barium carbonate powder is located at ½-⅔ above the lower part of the straight arm of the crucible in the vertical direction, and located at the distance of 10 mm-40 mm from the edge of the crucible in the horizontal direction. It is beneficial to the rapid dissolution of the barium carbonate powder into the silicon liquid, the process of decomposing the barium carbonate powder into barium oxide, and ultimately reacting barium oxide and silicon dioxide to form barium silicate is suppressed, and thus the presence of barium silicate also promotes formation of a dense crystalline quartz layer at a relatively low temperature in glassy quartz.

(2) According to the czochralski monocrystalline forming process and the application thereof in the present disclosure, the position of the crucible is changed in real time and the power is adjusted during the material melting process. Specifically, the position in which the upper edge of the crucible and the upper edge of the heater are flush is marked as 0 mm, it is positive above 0 mm and negative below 0 mm, at the beginning of melting, the crucible position is located at −70 mm to −50 mm, the crucible position is located at −50 mm-0 mm when the melting is performed for 4 h, and the crucible position is located at 0 mm-30 mm when the melting is performed for 6 h. When the linear size of the non-melted block in the later stage of the melting is 200 mm-300 mm, the crucible position should be at −30 mm-30 mm. Compared with the existing technologies, the crucible position is always at the lower limit during the material melting process, which does not affect the efficiency of the material melting and does not cause the edge collapse and deformation of the crucible. The baking temperature of barium powder is mild, which is beneficial to the formation of dense quartz on the inner wall of the crucible. In addition, the main heater power range of the melting power in the process of the present disclosure is 80 KW-90 KW, and the bottom heater power range is 60 KW-80 KW. The use of the lower power may not cause the temperature in the furnace to be too high, suppress the formation of crystalline quartz that is not a dense protective layer is suppressed, and the difficulty of crystallization is reduced.

(3) According to the czochralski monocrystalline forming process and the application thereof in the present disclosure, compared with the existing technologies, the number of times of first seeding and shouldering is apparently reduced, and the first seeding and shouldering survival rate is increased.

### DETAILED DESCRIPTION OF THE EMBODIMENTS

Experimental methods in the following embodiments of the present disclosure that do not indicate specific conditions are usually performed under conventional conditions or conditions recommended by manufacturers. Various commonly used chemical reagents used in the embodiments are all commercially available products.

Unless otherwise defined, all technical and scientific terms used in the present disclosure have the same meanings as those commonly understood by those skilled in the art belonging to the present disclosure. The terms used in the description of the present disclosure are only for the purpose of describing the specific embodiments and are not intended to limit the present disclosure.

The terms “including” and “having” in the present disclosure, as well as any variations thereof, are intended to cover non-exclusive inclusion. For example, a process, method, apparatus, product, or device that includes a series of steps is not limited to listed steps or modules, but may optionally also include steps that are not listed, or may optionally include other steps inherent to these process, method, product, or device.

In order to make purposes, technical schemes, and advantages of the present disclosure clearer, the present disclosure is further described in detail below in combination with the specific embodiments. It should be understood that these descriptions are merely exemplary and not intended to limit the scope of the present disclosure. Furthermore, in the following description, descriptions of well-known structures and technologies are omitted to avoid unnecessary confusion of the concepts of the present disclosure.

The present disclosure is further described below by the embodiments, but these embodiments are not intended to limit the scope of protection of the present disclosure.

### Embodiments 1-5

A czochralski monocrystalline forming process in Embodiments 1-5 specifically included the following steps.
S1, material preparation

Calculated by mass percentage, a solid silicon material used for crystal pulling was 55% (about 500 kg) of the feeding amount for a full crucible (36-inch quartz crucible); the addition amount of barium carbonate powder was 3.8 g; according to GB/T13389-2014, dopant gallium was added after being calculated according to the resistivity requirements, and its addition amount was 95 g; and a position of scattering the barium carbonate powder was located in the vertical direction at ½-⅔ above a lower part of a straight arm of the crucible, and located in the horizontal direction at a distance of 10 mm-40 mm from the edge of the crucible.
S2, material melting

A heater was started, and the solid silicon material in the crucible was melted into liquid silicon at a high temperature, the position of the crucible was changed during this process: a position in which the upper edge of the crucible and the upper edge of the heater were flush was marked as 0 mm, it was positive above 0 mm and negative below 0 mm, at the beginning of melting, the crucible position was located at −50 mm, the crucible position was located at 0 mm when the melting was performed for 4 h, and the crucible position was located at 30 mm when the melting was performed for 6 h; when the linear size of a non-melted block in the later stage of the melting was 200 mm-300 mm, the crucible position should be at 30 mm; and the main heater power range of the melting power was 85 KW, and the bottom heater power range was 70 KW.
S3, crystal seeding

After a seed crystal was inserted for high-temperature melting, fine crystal seeding was performed, the crystal seeding power was 65 KW, and dislocation caused by thermal shock during the insertion of the seed crystal into the liquid surface was eliminated.
S4, shoulder placement

By reducing the pulling speed to 60 mm/h, the power was gradually decreased by 12 KW compared to the crystal seeding power, and the crystal diameter was rapidly increased to a required diameter of a crystal rod.
S5, shoulder rotation

In the later stage of shoulder rotation, by increasing the pulling speed to 120 mm/h, the transition process of the crystal that mainly showed a flat growth trend to a relatively stable equal diameter state was changed.
S6, equal diameter

After the shoulder placement was completed, the crystal diameter was changed and the pulling speed was adjusted to 70 mm/h by using PID, as to adapt to stable diameter growth; and PID adjustment was performed on the equal diameter power by changing the crystal pulling speed, as to match the pulling speed in the setting of the process.
S7, finishing

After the equal diameter growth, the pulling speed was adjusted to be 1.5 times of the pulling speed before finishing, it was 105 mm/h, and the power was an equal diameter power plus 15 KW, it was 85 KW, so that the diameter of the crystal rod was reduced until the crystal rod was separated from the silicon liquid.

The positions of scattering the barium carbonate powder in Step S1 of the czochralski monocrystalline forming process in Embodiments 1-5 were specifically shown in Table 1:

TABLE 1
Position of scattering barium carbonate powder

| Embodiment | Vertical direction | Horizontal direction |
|---|---|---|
| 1 | Located at ½ above the lower part of | Located at 10 mm away from the |
| | the straight arm of the crucible | edge of the crucible |
| 2 | Located at ⅔ above the lower part of | Located at 20 mm away from the |
| | the straight arm of the crucible | edge of the crucible |
| 3 | Located at ½ above the lower part of | Located at 25 mm away from the |
| | the straight arm of the crucible | edge of the crucible |
| 4 | Located at ⅗ above the lower part of | Located at 30 mm away from the |
| | the straight arm of the crucible | edge of the crucible |
| 5 | Located at ⅔ above the lower part of | Located at 40 mm away from the |
| | the straight arm of the crucible | edge of the crucible |

The preparation was performed under the conditions of the czochralski monocrystalline forming process in Embodiments 1-5, and the number of times of first seeding and shouldering in Embodiments 1-5 was 2.3, 2.2, 2.0, 2.0, and 1.8 respectively.

### Embodiments 6-10

A czochralski monocrystalline forming process in Embodiments 6-10 specifically included the following steps.
S1, material preparation

Calculated by mass percentage, a solid silicon material used for crystal pulling was 55% (about 500 kg) of the feeding amount for a full crucible (36-inch quartz crucible); the addition amount of barium carbonate powder was 3.8 g; according to GB/T13389-2014, dopant gallium was added after being calculated according to the resistivity requirements, and its addition amount was 95 g; and a position of scattering the barium carbonate powder was located in the vertical direction at ⅔ above a lower part of a straight arm of the crucible, and located in the horizontal direction at a distance of 40 mm from the edge of the crucible.
S2, material melting

A heater was started, and the solid silicon material in the crucible was melted into liquid silicon at a high temperature, the position of the crucible was changed during this process: a position in which the upper edge of the crucible and the upper edge of the heater were flush was marked as 0 mm, it was positive above 0 mm and negative below 0 mm, at the beginning of melting, the crucible position was located at −70 mm to −50 mm, the crucible position was located at −50 mm-0 mm when the melting was performed for 4 h, and the crucible position was located at 0 mm-30 mm when the melting was performed for 6 h; when the linear size of a non-melted block in the later stage of the melting was 200 mm-300 mm, the crucible position should be at −30 mm-30 mm; and the main heater power range of the melting power was 85 KW, and the bottom heater power range was 70 KW.
S3, crystal seeding

After a seed crystal was inserted for high-temperature melting, fine crystal seeding was performed, the crystal seeding power was 65 KW, and dislocation caused by thermal shock during the insertion of the seed crystal into the liquid surface was eliminated.
S4, shoulder placement

By reducing the pulling speed to 60 mm/h, the power was gradually decreased by 12 KW compared to the crystal seeding power, and the crystal diameter was rapidly increased to a required diameter of a crystal rod.
S5, shoulder rotation

In the later stage of shoulder rotation, by increasing the pulling speed to 120 mm/h, the transition process of the crystal that mainly showed a flat growth trend to a relatively stable equal diameter state was changed.
S6, equal diameter

After the shoulder placement was completed, the crystal diameter was changed and the pulling speed was adjusted to 70 mm/h by using PID, as to adapt to stable diameter growth; and PID adjustment was performed on the equal diameter power by changing the crystal pulling speed, as to match the pulling speed in the setting of the process.
S7, finishing

After the equal diameter growth, the pulling speed was adjusted to be 1.5 times of the pulling speed before finishing, it was 105 mm/h, and the power was an equal diameter power plus 15 KW, it was 85 KW, so that the diameter of the crystal rod was reduced until the crystal rod was separated from the silicon liquid.

The positions of the crucible in Step S2 of the czochralski monocrystalline forming process in Embodiments 6-10 were specifically shown in Table 2:

TABLE 2
Position of crucible

| | At the | | | | | The linear size | |
|---|---|---|---|---|---|---|---|
| | beginning | | | | | of a non-melted | |
| Embodi- | of | At 4 h of | | At 6 h of | | material block was | |
| ment | melting | melting | | melting | | 200 mm-300 mm | |
| 6 | −70 mm | −50 | mm | 0 | mm | −30 | mm |
| 7 | −65 mm | −40 | mm | 8 | mm | −15 | mm |
| 8 | −60 mm | −25 | mm | 15 | mm | 0 | mm |
| 9 | −55 mm | −10 | mm | 22 | mm | 15 | mm |
| 10 | −50 mm | 0 | mm | 30 | mm | 30 | mm |

The preparation was performed under the conditions of the czochralski monocrystalline forming process in Embodiments 6-10, and the number of times of first seeding and shouldering in Embodiments 6-10 was 2.3, 2.2, 2.0, 2.1, and 1.8 respectively.

### Embodiments 11-13

A czochralski monocrystalline forming process in Embodiments 11-13 specifically included the following steps.
S1, material preparation

Calculated by mass percentage, a solid silicon material used for crystal pulling was 55% (about 500 kg) of the feeding amount for a full crucible (36-inch quartz crucible); the addition amount of barium carbonate powder was 3.8 g; according to GB/T13389-2014, dopant gallium was added after being calculated according to the resistivity requirements, and its addition amount was 95 g; and a position of scattering the barium carbonate powder was located in the vertical direction at ⅔ above a lower part of a straight arm of the crucible, and located in the horizontal direction at a distance of 40 mm from the edge of the crucible.
S2, material melting

A heater was started, and the solid silicon material in the crucible was melted into liquid silicon at a high temperature, the position of the crucible was changed during this process: a position in which the upper edge of the crucible and the upper edge of the heater were flush was marked as 0 mm, it was positive above 0 mm and negative below 0 mm, at the beginning of melting, the crucible position was located at −50 mm, the crucible position was located at 0 mm when the melting was performed for 4 h, and the crucible position was located at 30 mm when the melting was performed for 6 h; when the linear size of a non-melted block in the later stage of the melting was 200 mm-300 mm, the crucible position should be at 30 mm; and the main heater power range of the melting power was 80 KW-90 KW, and the bottom heater power range was 60 KW-80 KW.
S3, crystal seeding

After a seed crystal was inserted for high-temperature melting, fine crystal seeding was performed, and dislocation caused by thermal shock during the insertion of the seed crystal into the liquid surface was eliminated.
S4, shoulder placement

By reducing the pulling speed to 60 mm/h, the power was gradually decreased by 12 KW compared to the crystal seeding power, and the crystal diameter was rapidly increased to a required diameter of a crystal rod.
S5, shoulder rotation

In the later stage of shoulder rotation, by increasing the pulling speed to 120 mm/h, the transition process of the crystal that mainly showed a flat growth trend to a relatively stable equal diameter state was changed.
S6, equal diameter

After the shoulder placement was completed, the crystal diameter was changed and the pulling speed was adjusted to 70 mm/h by using PID, as to adapt to stable diameter growth; and PID adjustment was performed on the equal diameter power by changing the crystal pulling speed, as to match the pulling speed in the setting of the process.
S7, finishing

After the equal diameter growth, the pulling speed was adjusted to be 1.5 times of the pulling speed before finishing, it was 105 mm/h, and the power was an equal diameter power plus 15 KW, it was 85 KW, so that the diameter of the crystal rod was reduced until the crystal rod was separated from the silicon liquid.

The melting power in Step S2 of the czochralski monocrystalline forming process in Embodiments 11-13 was specifically shown in Table 3:

TABLE 3
Melting power

| Embodiment | Main heater power | Bottom heater power |
|---|---|---|
| 11 | 80 KW | 60 KW |
| 12 | 85 KW | 70 KW |
| 13 | 90 KW | 80 KW |

The preparation was performed under the conditions of the czochralski monocrystalline forming process in Embodiments 11-13, and the number of times of first seeding and shouldering in Embodiments 11-13 was 1.9, 1.8, and 2.0 respectively.

### Contrast Embodiment 1

The difference from Embodiment 5 was that Steps S1-S2 of the czochralski monocrystalline forming process were different, specifically:

A position of scattering barium carbonate powder in Step S1 was located in the vertical direction at ⅔ above a lower part of a straight arm of the crucible, and located in the horizontal direction at a distance of 40 mm from the edge of the crucible;

In Step S2, from the beginning to the ending of melting, the crucible position was always kept at the lower limit (about −110 mm); and the main heater power range of the melting power was 110 KW, and the bottom heater power range was 90 KW.

### Contrast Embodiment 2

The difference from Embodiment 10 was that Steps S1-S2 of the czochralski monocrystalline forming process were different, specifically:

A position of scattering barium carbonate powder in Step S1 was located in the vertical direction at ½ above a lower part of a straight arm of the crucible, and located in the horizontal direction at a distance of 40 mm from the edge of the crucible;

In Step S2, from the beginning to the ending of melting, the crucible position was always kept at the lower limit (about −110 mm); and the main heater power range of the melting power was 85 KW, and the bottom heater power range was 70 KW.

### Contrast Embodiment 3

The difference from Embodiment 12 was that Steps S1-S2 of the czochralski monocrystalline forming process were different, specifically:

A position of scattering barium carbonate powder in Step S1 was located in the vertical direction at ½ above a lower part of a straight arm of the crucible, and located in the horizontal direction at a distance of 40 mm from the edge of the crucible;

In Step S2, at the beginning of melting, the crucible position was at −50 mm, the crucible position was at 0 mm when the melting was performed for 4 h, and the crucible position was at 30 mm when the melting was performed for 6 h, when the linear size of a non-melted material block in the later stage of the material melting was 200 mm-300 mm, the crucible position should be at 30 mm, the main heater power range of the melting power was 110 KW, and the bottom heater power range was 90 KW.

The number of times of first seeding and shouldering obtained from the steps of the czochralski monocrystalline forming process in Contrast embodiments 1-3 was shown in Table 4.

TABLE 4
Number of times of first seeding and shouldering

| Contrast | Number of times of first seeding and |
|---|---|
| embodiment | shouldering |
| 1 | 3.1 |
| 2 | 2.8 |
| 3 | 3.0 |

According to the results of Embodiments 1-13 and Contrast embodiments 1-3, it might be seen that in the czochralski monocrystalline forming process of the present disclosure, when the position of scattering the barium powder was located in the vertical direction at ⅔ above the lower part of the straight arm of the crucible and located in the horizontal direction at the distance of 40 mm from the edge of the crucible, at the beginning of melting, the crucible position was located at −50 mm, the crucible position was located at 0 mm when the melting was performed for 4 h, and the crucible position was located at 30 mm when the melting was performed for 6 h. When the linear size of the non-melted material block in the later stage of the material melting was 200 mm-300 mm, the crucible position should be at 30 mm. This method of placing the crucible position was used to pull the crystal, when the main heater power of the melting power was 85 KW, and the bottom heater power was 70 KW, the acquired number of times of seeding and shouldering was the lowest.

It should be noted that the specific features, structures, materials, or characteristics described in the description might be combined in any way. In order to make the description concise, all possible combinations of the various technical features in the above embodiments were not described. In the case without contradiction, those skilled in the art might integrate and combine the different embodiments and features described in the description.

The above embodiments only express several implementation modes of the present disclosure, and its descriptions are more specific and detailed, but should not be understood as limiting the scope of the invention patent. It should be pointed out that for those of ordinary skill in the art, a plurality of modifications and improvements may also be made without departing from the concepts of the present disclosure, and these are all within the scope of protection of the present disclosure. Therefore, the scope of protection of the present disclosure patent should be based on the appended claims.

1. A czochralski monocrystalline forming process, comprising the following steps:
S1, material preparation
loading a solid silicon material, a dopant, and barium carbonate powder into a quartz crucible container;
S2, material melting
starting a heater, and melting the solid silicon material in the crucible into liquid silicon at a high temperature;
S3, crystal seeding
after inserting a seed crystal for high-temperature melting, performing fine crystal seeding, wherein the crystal seeding power is 60 KW-80 KW;
S4, shoulder placement
adjusting the pulling speed to 30 mm/h-100 mm/h, wherein the power is decreased by 8 KW-15 KW compared to the crystal seeding power, so that the crystal diameter is rapidly increased to a required diameter of a crystal rod;
S5, shoulder rotation
in the later stage of shoulder rotation, by increasing the pulling speed, changing the transition process of the crystal that mainly shows a flat growth trend to a relatively stable equal diameter state;
S6, equal diameter
after completing the shoulder placement, adjusting the pulling speed, so that the diameter of the crystal rod basically remains unchanged, and the diameter of the crystal rod is kept between ±2 mm;
S7, finishing
after the equal diameter growth, adjusting the pulling speed and power, so that the diameter of the crystal rod is reduced until the crystal rod is separated from the silicon liquid.

2. The czochralski monocrystalline forming process according to claim 1, wherein calculated by mass percentage, the addition amount of the solid silicon material in Step S1 is 50%-60% of the full crucible feeding amount; the addition amount of the barium carbonate powder is 2 g-5 g; and the addition amount of the dopant is calculated according to the resistivity requirements.

3. The czochralski monocrystalline forming process according to claim 1, wherein the crucible in Step S1 is a 32-inch-40-inch quartz crucible.

4. The czochralski monocrystalline forming process according to claim 1, wherein the dopant in Step S1 comprises one or a combination of a boron mother alloy, a gallium mother alloy, and a phosphorus mother alloy.

5. The czochralski monocrystalline forming process according to claim 1, wherein the position of scattering the barium carbonate powder in Step S1 is located in the vertical direction at ½-⅔ above a lower part of a straight arm of the crucible, and located in the horizontal direction at a distance of 10 mm-40 mm from the edge of the crucible.

6. The czochralski monocrystalline forming process according to claim 1, wherein during the material melting process in Step S2, the position of the crucible is changed: a position in which the upper edge of the crucible and the upper edge of the heater are flush is marked as 0 mm, it is positive above 0 mm and negative below 0 mm, at the beginning of melting, the crucible position is located at −70 mm to −50 mm, the crucible position is located at −50 mm-0 mm when the melting is performed for 4 h, and the crucible position is located at 0 mm-30 mm when the melting is performed for 6 h; and when the linear size of a non-melted block in the later stage of the melting is 200 mm-300 mm, the crucible position is located at −30 mm-30 mm.

7. The czochralski monocrystalline forming process according to claim 1, wherein during the material melting process in Step S2, the main heater power range of the melting power is 80 KW-90 KW, and the bottom heater power range is 60 KW-80 KW.

8. The czochralski monocrystalline forming process according to claim 1, wherein the number of times of first seeding and shouldering during the crystal seeding and shouldering process in Step S3 is 1.5 times-2.5 times.

9. Monocrystalline silicon prepared by the czochralski monocrystalline forming process according to claim 1.

10. An application of the monocrystalline silicon according to claim 9 in a semiconductor.

11. The czochralski monocrystalline forming process according to claim 1, wherein the adjustment of the pulling speed in Step S6 is achieved by using proportion integration differentiation (PID) to adjust the pulling speed.

12. The czochralski monocrystalline forming process according to claim 11, wherein the adjustment of the pulling speed in Step S6 is 50 mm/h-140 mm/h.

13. The czochralski monocrystalline forming process according to claim 1, wherein the adjustment of the pulling speed in Step S7 is 1 times-1.5 times of the pulling speed before the finishing.

14. The czochralski monocrystalline forming process according to claim 13, wherein the adjustment of the pulling speed in Step S7 is 90 mm/h-150 mm/h.

15. The czochralski monocrystalline forming process according to claim 1, wherein the power in Step S7 is an equal diameter power plus 10 KW-20 KW.

16. The czochralski monocrystalline forming process according to claim 15, wherein the power in Step S7 is 70 KW-90 KW.
